(19) United States
(12) Patent Application Publication
(10) Pub. No.: US 2024/0354461 A1
(43) Pub. Date: Oct. 24, 2024

(54) METHOD AND MULTI-ENGINE ROTORCRAFT FOR SIMULATING AN ENGINE FAILURE

(71) Applicant: AIRBUS HELICOPTERS, Marignane Cedex (FR)

(72) Inventors: Guillaume DUMUR, Salon De Provence (FR); Julien FRAENZEL, Peynier (FR)

(73) Assignee: AIRBUS HELICOPTERS, Marignane Cedex (FR)

(21) Appl. No.: 18/442,369

(22) Filed: Feb. 15, 2024

(30) Foreign Application Priority Data
Apr. 19, 2023 (FR) 2303889

(51) Int. Cl. G06F 30/15; B64C 27/00

(52) U.S. Cl. CPC G06F 30/15; B64C 27/00

(57) ABSTRACT

A method for simulating an engine failure on a rotorcraft comprising several engines for setting a rotary wing in motion. The method comprises a training mode that comprises controlling each engine with a controller in order to simulate an engine failure, this control comprising limiting the power of each engine to a respective control restriction value. The training mode comprises the following steps: i) determining, with the controller, a maximum mass at least as a function of external conditions, and an initial mass of the rotorcraft at least as a function of an unladen mass of the rotorcraft, a mass of a crew present in the rotorcraft, and an estimated mass of fuel on-board; ii) comparing, with the controller, the initial mass with the maximum mass; and iii) determining, with the controller, each control restriction value as a function of the comparison.

### CROSS-REFERENCE TO RELATED APPLICATIONS

This application claims priority to French patent application No. FR 23 03889 filed on Apr. 19, 2023, the disclosure of which is incorporated in its entirety by reference herein.

### TECHNICAL FIELD

The present disclosure relates to a method and a multi-engine rotorcraft for simulating an engine failure.

### BACKGROUND

A multi-engine rotorcraft comprises a rotary wing set in motion by a power plant having at least two engines.

Under normal conditions, i.e., except in the event of an engine failure or a simulation, each engine can thus operate in a plurality of standard ratings. These standard operating ratings under normal conditions may comprise a continuous operating rating wherein the engine can provide a maximum continuous power or MCP, and a take-off operating rating wherein the engine can provide a maximum take-off power MTOP greater than the maximum continuous power MCP.

The engines are also dimensioned so that the power plant produces sufficient driving power to ensure flight in the event of total failure of one engine. Each engine can therefore operate in a plurality of emergency ratings in the event of failure of another engine. These emergency ratings are sometimes referred to as “one engine inoperative” or OEI ratings. These emergency ratings may comprise:
a first emergency rating limited to a super-contingency power referred to as OEI30″, that can be used for a period of the order of thirty consecutive seconds, this first emergency rating being able to be used approximately three times during a flight;
a second emergency rating limited to a maximum contingency power referred to as OEI2′, that can be used for a period of the order of two minutes; and
a third emergency rating limited to an intermediate contingency power referred to as OEIcont, that can be used, for example, for a period covering the end of the flight.

The maximum powers associated with each rating are defined, in particular, as a function of external conditions.

In order to train aircraft pilots for a total engine failure and the associated degraded operation, a rotorcraft may have a mode referred to as training mode.

In the training mode, the power plant as a whole produces a “reduced overall power” with the engines, that is capped at the power of an emergency rating. To this end, the engines may produce equal or different powers.

According to another aspect, the performances of a rotorcraft depend on the mass of this rotorcraft. The power produced by a power plant varies according to the altitude of the aircraft, particularly when turboshaft engines are used. A manufacturer may thus establish the maximum authorized mass of the rotorcraft depending on the anticipated flight altitude.

Therefore, if the training mode is activated on a rotorcraft whose mass is far lower than its maximum mass, the power required by the rotorcraft may be less than the maximum power of the tested emergency rating. This training is then not optimal.

However, this type of training flight is often carried out in a relatively lightweight helicopter comprising only the student pilot and the instructor. In order to optimize the training, the instructor and the student may add extra ballast the rotorcraft. This solution does help to bring the mass of the rotorcraft close to its maximum authorized mass but is nonetheless restrictive.

Rotorcraft may be provided with various systems for performing a training flight to train for the failure of a rotorcraft engine.

In this context, document U.S. Pat. No. 5,873,546 A discloses modules and methods for weighting the power of a multi-engine power plant of a helicopter. A training mass is assessed depending, in particular, on ambient climatic conditions such as temperature and altitude.

Document EP 2 254 793 describes a rotorcraft provided with an interface that has two switches for respectively simulating an aircraft with a maximum on-board load and an aircraft with a maximum on-board load and carrying a maximum load with a hook.

Document EP 2 624 239 describes a rotorcraft provided with an adjustment means that may be used by an instructor to adapt the reduced overall power and simulate different failure configurations.

Document US 2009/186320 A1 is also known.

The document “Getting to grips with aircraft performance”, Jan. 1, 2002 (2002 Jan. 1), pages 1-216, XP093085967, retrieved from the Internet at the following URL: https://skybrary.aero/sites/default/files/bookshelf/2263.pdf (retrieved on 2023 Sep. 26) is also known.

The document “How much does a helicopter weigh?”, Oct. 26, 2022 (2022 October 26), XP093085983, retrieved from the Internet at the following URL: https://www.aeroclass.org/How-much-does-a-helicopter-weigh/(retrieved on 2023 Sep. 26) is also known.

### SUMMARY

An object of the present disclosure is thus to propose an innovative method for simulating an engine failure on a multi-engine rotorcraft.

The disclosure therefore relates to a method for simulating an engine failure on a rotorcraft, the rotorcraft comprising a power plant provided with several engines that together produce an overall power for setting a rotary wing in motion, at least one engine functioning by burning fuel, each engine having a control parameter capped by a controller at a limit control value during at least one emergency rating applicable in the event of failure of another engine, the method comprising a training mode that comprises controlling each engine with the controller in order to simulate an engine failure, said controlling of each engine with the controller comprising capping the control parameter of each engine at a respective control restriction value.

The training mode comprises the following steps:
determining, possibly during flight upon initialization of the training mode, with the controller, an initial mass of said rotorcraft, at least as a function of an unladen mass of the rotorcraft, a set mass of a crew present in the rotorcraft, and a mass of fuel on-board and estimated;
determining, during flight, and possibly upon initialization of the training mode, a maximum mass of the rotorcraft established at least as a function of external conditions;
comparing, during flight, with the controller, the initial mass with the maximum mass; and
determining, with the controller, each control restriction value as a function of comparing, during flight, with the controller, the initial mass with the maximum mass and of said limit control value.

The control parameter may be an engine torque or a power, for example.

The maximum mass is established by the controller, in particular as a function of external conditions, for example using a stored mass model. For example, the controller comprises a spreadsheet or a mathematical law providing the maximum mass as a function of the external conditions.

This method therefore relates to the application of a training mode, for example following the activation of this training mode with a human-machine control interface.

The controller is thus configured to determine an initial mass of the rotorcraft, i.e., substantially close to the actual mass of the rotorcraft when the training mode is initialized. This controller compares the initial mass with the maximum mass and then controls the engines so that the weight/power ratio of the rotorcraft when the training mode is applied is substantially equivalent to the weight/power ratio that the rotorcraft would have with its maximum mass and a failed engine when the current emergency rating is applied. In other words, the lighter the rotorcraft, the lower the control restriction values of the emergency rating or ratings.

To this end, the controller adapts the value of each control restriction value. For example, the controller applies a mathematical model, possibly established by tests and/or simulations, to establish the control restriction values as a function of the comparison between the initial mass and the maximum mass.

For example, on a twin-engine rotorcraft, one engine may be dimensioned to produce a torque of 600 newton-meters in the current emergency rating with the current external conditions, the other engine not producing any power because it has failed. In order to simulate this situation on a conventional rotorcraft, the two engines are controlled to each produce, for example, an engine torque of 300 newton-meters. According to the disclosure, if the rotorcraft has an initial mass of the order of 80 percent of the maximum mass, the controller may control each engine to cap the engine torque at 240 newton-meters, i.e., 80 percent of the abovementioned 300 newton-meters.

Therefore, the method of the disclosure can be used to adapt the control restriction values of the engines during the training mode as a function of the initial mass of the rotorcraft in order to simulate an engine failure occurring on a rotorcraft that is at its maximum mass with the current external conditions. The training is therefore optimized by placing the rotorcraft in conditions close to the most unfavorable conditions, i.e., an engine failure in a rotorcraft that is at its maximum mass.

The method according to the disclosure may also include one or more of the following features.

The external conditions may comprise an external pressure and an external temperature of the air present around the rotorcraft, said initialization of the training mode comprising estimating the external pressure with an external pressure sensor of the controller and the external temperature with an external temperature sensor of the controller.

This feature makes it possible to take into consideration the impact of external conditions on the operation of the engines.

Irrespective of this feature and according to a first alternative of the disclosure, the method may comprise measuring a current quantity of fuel in the rotorcraft with a gauge of the controller, then estimating said mass of fuel as a function of the current quantity upon initialization of the training mode.

The current quantity may be a current mass or a current volume of fuel.

According to this first alternative, if the current quantity is a current mass of fuel, the mass of fuel is equal to the current quantity.

However, if the current quantity is a current volume of fuel, the mass of the fuel may correspond to the product of the current volume of the fuel present in the rotorcraft upon initialization of the training mode and the density of the fuel. This density may be stored in the controller. The controller may possibly comprise a list of fuels and an interface on which a crew can select the on-board fuel.

This first alternative makes it possible to accurately estimate the initial mass upon initialization of the training mode, i.e., after this training mode has been activated.

According to a second alternative, said training mode may comprise setting a pre-flight quantity of fuel with a human-machine interface for setting fuel parameters of the controller, the method comprising: i) estimating a quantity of fuel consumed prior to initialization of the training mode; and ii) estimating said mass of fuel as a function of the pre-flight quantity of fuel and the consumed quantity of fuel, or indeed the density of the fuel.

According to the second alternative, a crew manually sets the pre-flight quantity of on-board fuel, i.e., the mass or the volume of on-board fuel. The controller is then configured to calculate the consumed quantity of fuel using at least one flowmeter, for example, the product of a flow rate and a period of time allowing a volume to be deduced. The controller is also configured to deduce the mass of fuel at the time of initialization of the training mode, by taking into consideration the density of the fuel if one of said quantities is a volume of fuel. For example, the pre-flight quantity and the consumed quantity of fuel are volumes of fuel, the mass of fuel then being equal to the product of the density and the arithmetic difference of the pre-flight quantity minus the consumed quantity of fuel.

This second alternative makes it possible to accurately estimate the initial mass.

According to the second alternative, the method may therefore comprise setting the pre-flight quantity before the engines are started, using a human-machine interface for setting fuel parameters of the controller, the pre-flight quantity being locked after said start-up.

According to a third alternative, the mass of fuel may be set with a human-machine interface for setting fuel parameters of the controller.

A crew may manually set the mass of fuel, for example upon initialization of the training mode, in order to test a particular configuration or adapt the test to a student's level.

The method may possibly comprise setting the mass of fuel before the engines are started, the mass of fuel being locked after said start-up.

A given rotorcraft may possibly be configured to be able to implement several alternatives. For example, the rotorcraft may comprise a human-machine interface for making a choice, for choosing the desired alternative, for example depending on the pedagogical aim of the pilot training in OEI mode.

Regardless of the alternative, the method may comprise selecting a type of training with a human-machine selection interface of the controller, determining, during flight, with the controller, of the maximum mass, depending on the type of training selected with the human-machine selection interface.

The power to be supplied by the engines varies as a function of the type of training. The method may therefore take it into consideration.

Said type of training may possibly be chosen from a list comprising: category A training requiring the possibility of continuing the flight, and category B training requiring the possibility of landing safely.

According to one possibility compatible with the preceding possibilities, comparing, with the controller, of the initial mass with the maximum mass may comprise establishing a proportional ratio between the initial mass and the maximum mass.

The ratio may be equal to 1, by default, for safety reasons.

Therefore, according to a first variant, determining, with the controller, of each control restriction value as a function of said comparison, may comprise, for each engine: i) estimating a calculation control value as a function of said proportional ratio and the limit control value; then ii) determining the control restriction value as a function of said calculation control value and a distribution coefficient specific to each control restriction value.

The calculation control value may be equal to the product of the proportional ratio and the limit control value. A control restriction value may be equal to the product of the calculation control value and the associated distribution coefficient.

In this case, the controller estimates the limit control values in a conventional manner, then deduces the control restriction values therefrom. For example, the distribution coefficient may be equal to the number of engines in operation.

Alternatively, determining, with the controller, of each control restriction value as a function of said comparison, may comprise, for each engine: i) estimating an intermediate value as a function of a distribution coefficient specific to each control restriction value and the limit control value; then ii) determining each control restriction value as a function of said intermediate value and said proportional ratio.

The intermediate value may be equal to the product of the associated distribution coefficient and the limit control value. A control restriction value may be equal to the product of the intermediate value and the proportional ratio.

This alternative may be implemented easily in an aircraft comprising engine computers which cap a control parameter at the intermediate value for each engine during the training mode. Indeed, the engine computers may be modified to receive the proportional ratio and apply it to the determined intermediate value in a conventional manner.

According to one possibility compatible with the preceding possibilities, the method may comprise setting the unladen mass, before the engines are started, with a human-machine unladen mass interface of the controller, and setting the mass of a crew present in the rotorcraft, before the engines are started, with a human-machine crew mass interface of the controller, the unladen mass and the mass of a crew present in the rotorcraft being locked after said start-up.

According to one example, the unladen mass may be equal to the sum of a bare mass of the rotorcraft, that is set with the human-machine unladen mass interface or stored, a mass of optional equipment set with the human-machine unladen mass interface, and a cargo mass set with the human-machine unladen mass interface.

According to another example, the unladen mass may be equal to the sum of a bare mass of the empty aircraft, that is set with the human-machine unladen mass interface or stored, and may include installed optional equipment, and a cargo mass set with the human-machine unladen mass interface.

According to one example, the unladen mass may be equal to the mass set with the human-machine unladen mass interface.

According to one possibility compatible with the preceding possibilities, the method may comprise measuring a speed of rotation of the rotary wing with a rotation speed sensor of the controller, automatically disengaging the training mode with the controller as soon as the speed of rotation is less than a stored threshold, and generating an alert indicating the disengagement.

The training mode may be deactivated automatically if the overall power produced is insufficient to rotate the rotary wing at a minimum speed of rotation. The crew is then informed.

The disclosure also relates to a rotorcraft comprising a power plant provided with several engines that together produce an overall power for setting a rotary wing in motion, each engine producing a power capped by a controller at a limit power value when at least one emergency rating is applied in the event of failure of at least one other engine.

The controller is thus configured to apply the method of the disclosure.

To this end, the controller may, for example, comprise one fuel metering valve for each engine, controlled by a control unit. The control unit may be in communication with at least one of the following devices: an external pressure sensor, an external temperature sensor, a rotation speed sensor measuring the speed of rotation of the rotary wing, at least one engine control sensor, a human-machine unladen mass interface, a human-machine crew mass interface, a human-machine selection interface, a human-machine interface for making a choice, and a human-machine interface for setting fuel parameters.

### BRIEF DESCRIPTION OF THE DRAWINGS

The disclosure and its advantages appear in greater detail in the context of the following description of embodiments given by way of illustration and with reference to the accompanying figures, wherein:

FIG. 1 is a view of a rotorcraft according to the disclosure;

FIG. 2 is a logic diagram showing the method according to the disclosure;

FIG. 3 is a logic diagram showing a method for estimating the mass of fuel;

FIG. 4 is a logic diagram showing a method for estimating the mass of fuel; and

FIG. 5 is a logic diagram showing a method for estimating the mass of fuel.

### DETAILED DESCRIPTION

Elements that are present in more than one of the figures are given the same references in each of them.

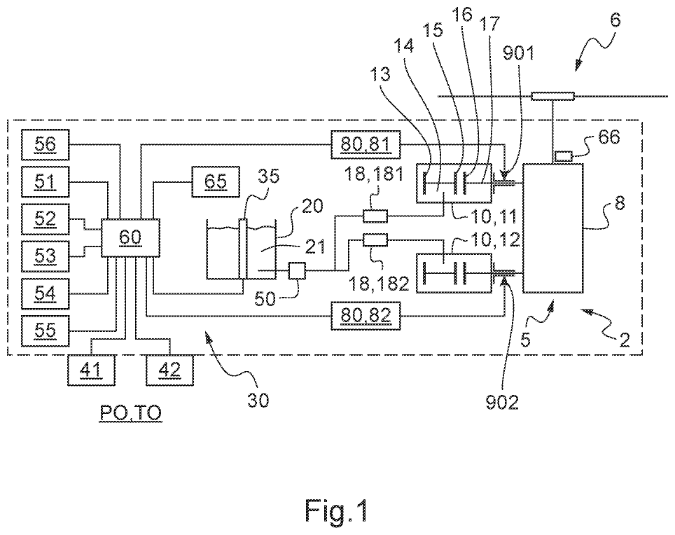

FIG. 1 shows an example of a rotorcraft 1 according to the disclosure. This rotorcraft 1 comprises a rotary wing 6.

The rotorcraft 1 also comprises a power plant 2 for rotating the rotary wing 6, for example in order to ensure the lift, and indeed the forward movement, of this rotorcraft 1. This power plant 2 is provided with at least two engines 10. Reference 10 denotes any engine, and references 11, 12 denote particular engines in order to identify a specific engine 10 as required.

At least one, or indeed each engine 10, is supplied with fuel 21 by at least one tank 20, via a fuel circuit.

According to one example, at least one engine 10 may be a turboshaft engine. Such a turboshaft engine 10 comprises a gas generator that is provided with at least one compression turbine 13, a combustion chamber 14 into which fuel is injected and at least one expansion turbine 15 constrained to rotate with the compression turbine or turbines 13. Moreover, the turboshaft engine 10 may comprise at least one free turbine 16 that sets a power shaft 17 of the engine in motion directly or indirectly.

Irrespective of the type of engines, each engine 10 may comprise a power shaft 17 connected to a power transmission system 5. The power transmission system 5 is connected to the rotary wing 6 in a conventional manner. By way of illustration, the power transmission system 5 may be provided with a gearbox that is mechanically interposed between the engines 10 and the rotary wing 6. The power transmission system 5 may comprise at least one free-wheel, and/or at least one connecting shaft, and/or at least one connector allowing misalignments, etc.

Moreover, the engines 10 are heat engines that operate with fuel 21. The engines 10 can operate in a plurality of ratings, and in particular one of the abovementioned ratings, i.e., the continuous operating rating, the take-off operating rating, the first emergency rating, the second emergency rating and the third emergency rating. Therefore, the rotorcraft 1 comprises a control system referred to more simply as a “controller 30” for controlling the power or the torque delivered by each engine 10 with its power shaft 17 as a function, in particular, of the applied current rating.

The controller 30 may comprise one fuel metering valve 18 for each engine 10, for example on the fuel circuit connecting the tank or tanks 20 to the associated engine 10. Each engine 10 is then connected, via its own fuel metering valve 18, to at least one fuel tank 20. Reference 18 denotes any fuel metering valve, references 181, 182 denoting particular fuel metering valves of the two engines 11, 12 respectively.

Moreover, the controller 30 may comprise at least one flowmeter 50 arranged on the fuel circuit for assessing the quantity of fuel consumed since the engines 10 were started.

Moreover, the controller 30 may comprise a gauge 35 for assessing the quantity of fuel stored in the tank or tanks 20. Such a gauge 35 may comprise, for example, one or more conventional fuel level indicators, this example being given simply in order to illustrate the controller 30.

Furthermore, the controller 30 may comprise one engine computer 80 for each engine 10. For example, each engine computer 80 may comprise at least one processor and at least one memory, at least one integrated circuit, at least one programmable system, or at least one logic circuit, these examples not limiting the scope to be given to the term “engine computer”. The engine computers may communicate with each other via wired or wireless links.

According to the described example, the power plant 2 comprises two engine computers 81, 82 respectively controlling the two engines 11, 12. Each engine computer 81, 82 is configured to control the associated engine 11,12 and make it operate according to the required rating, for example so that the controlled engine 11,12 has a control parameter capped at a limit control value of this rating. The control parameter may be the engine torque or the power produced by the engine, for example.

The limit control value is established for a rotorcraft 1 in a conventional manner. For example, each engine computer determines, depending on the rating to be applied, a first torque limit to be observed in order not to damage the power transmission system 5, as well as a temperature limit of the engine in question converted into a second torque limit and a rotational speed limit of the gas generator of the engine converted into a third torque limit and determined as a function of the external conditions, the limit control value being equal to the smallest of these torque limits.

Each engine computer 81, 82 may in particular control the fuel metering valve 181, 182 of the associated engine 11, 12. Each engine computer 81,82 may be connected to a plurality of control sensors in order to control the associated engine 11, 12, such as, for example, a torquemeter 901, 902 measuring an engine torque on a rotating member. Such a rotating member may be a power shaft 17 of an engine 10. For example, the fuel metering valve 181, 182 is controlled via the implementation of a control loop that is intended to keep the torque developed by the rotating member less than or equal to the current limit control value.

The controller 30 may further comprise a control unit 60 in communication with the engine computers 80. By way of example, the control unit 60 may comprise at least one processor and at least one memory, at least one integrated circuit, at least one programmable system, or at least one logic circuit, these examples not limiting the scope to be given to the term “control unit”. The control unit 60 may communicate via wired or wireless links with each engine computer 80, or may be merged with at least one engine computer 80.

The control unit 60 may communicate via wired or wireless links with the gauge 35 and the flowmeter 50, if applicable.

Irrespective of its composition, the control unit 60 can communicate via a wired or wireless link with at least one alerter 65 for providing information to a pilot. Such an alerter 65 may, for example, comprise a display capable of displaying a message, a light-emitting diode that lights up at the command of the control unit 60, a loudspeaker, etc.

Furthermore, the control unit 60 may communicate with one or more human-machine interfaces. Each human-machine interface may comprise at least one member that can be operated by a pilot, such as a knob or a lever, a touch screen, a voice command, etc.

Therefore, the control unit 60 may communicate with a human-machine interface 51 for setting fuel parameters. This human-machine interface 51 for setting fuel parameters transmits a signal to the control unit 60 indicating a pre-flight quantity of fuel, i.e., a pre-flight mass or a volume of fuel.

The term “signal” refers to a digital, analog, optical or electrical signal.

The control unit 60 may communicate with a human-machine selection interface 52. This human-machine selection interface 52 transmits a signal to the control unit 60 indicating a chosen type of training. For example, the type of training is chosen from a list comprising category A training requiring the possibility of continuing the flight after an engine failure and category B training requiring the possibility of landing safely after an engine failure.

The control unit 60 may communicate with a human-machine unladen mass interface 53. The expression “unladen mass” refers to the mass of the rotorcraft 1 without fuel and without crew. This human-machine unladen mass interface 53 transmits a signal referred to for convenience as the “unladen mass signal” to the control unit 60, indicating an unladen mass of the rotorcraft 1. This unladen mass may vary depending on the optional equipment arranged on the rotorcraft 1, or ballast taken on board. The human-machine unladen mass interface 53 can be used to set all of the parameterizable items that influence the unladen mass, such as the bare mass of the rotorcraft, the cargo mass and the mass of equipment.

The control unit 60 may communicate with a human-machine crew mass interface 54. This human-machine crew mass interface 54 transmits a signal, referred to for convenience as the “crew mass signal”, to the control unit 60, indicating the mass of the crew, i.e., the mass of all of the occupants of the rotorcraft 1.

The control unit 60 may communicate with a human-machine interface 55 for activating the training mode. This human-machine interface 55 for activating the training mode transmits a signal to the control unit 60 indicating that the training mode has been activated.

The control unit 60 may communicate with a human-machine density interface 54. This human-machine density interface 54 transmits a signal, referred to for convenience as the “density signal”, to the control unit 60, indicating the density of the on-board fuel. This signal may comprise either the density as such or the type of fuel, the control unit storing the density associated with each type of fuel.

Moreover, the control unit 60 may be connected to one or more sensors, via wired or wireless links, for example.

The control unit 60 may be connected to an external pressure sensor 41 transmitting a signal referred to for convenience as the “pressure signal”, indicating an external pressure PO of the air surrounding the rotorcraft 1.

Moreover, the control unit 60 may be connected to an external temperature sensor 42 transmitting a signal referred to for convenience as the “temperature signal”, indicating an external temperature TO of the air surrounding the rotorcraft 1.

Moreover, the control unit 60 may be connected to a rotation speed sensor 66 transmitting a signal referred to for convenience as the “rotation speed signal”, indicating a speed of rotation NR of the rotary wing. Such a sensor is known from the prior art.

In this context, during a normal operating mode, each fuel metering valve 18 is controlled by the corresponding engine computer 80 in order for the power plant 2 to produce an overall power WGLOB.

In the event of failure of one of the engines 10, each fuel metering valve 18 of an engine remaining in operation is controlled by the corresponding engine computer 80 in order for the engine 10 to produce an emergency driving power with its power shaft 17, a control parameter of the engine in operation being capped at a limit control value corresponding to the current emergency rating.

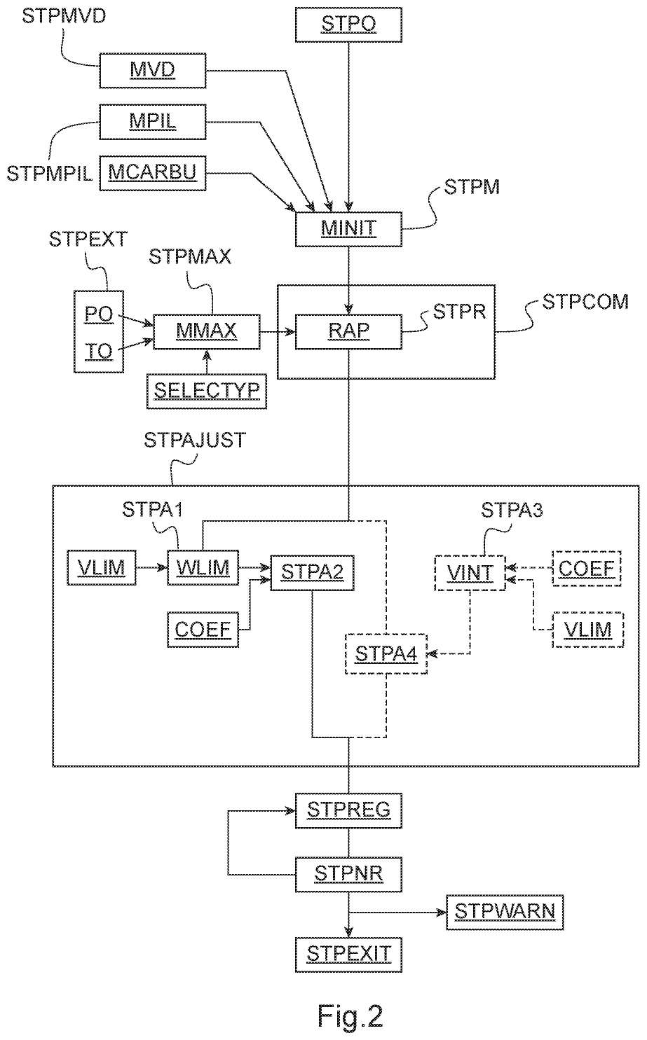

FIG. 2 shows examples of a method for simulating an engine failure that can be implemented by the rotorcraft of FIG. 1.

To this end, the method may comprise activating STPO a training mode. For example, an instructor or a student pilot operates the human-machine interface 55 for activating the training mode. This human-machine interface 55 for activating the training mode transmits a signal to the control unit 60, that activates the training mode.

Irrespective of how it is activated, the training mode comprises determining STPM an initial mass MINIT of the rotorcraft 1, with the controller 30, at least as a function of the set unladen mass MVD of the rotorcraft 1, the set mass MPIL of a crew, and a mass of fuel MCARBU on-board. The type of training may also be taken into consideration.

To this end, in preparation for this simulation, the method may comprise setting STPMVD the unladen mass MVD before the engines 10 are started. A crew operates the human-machine unladen mass interface 53, that transmits an unladen mass signal to the control unit 60. The control unit 60 decodes the unladen mass signal, then deduces therefrom and stores an unladen mass MVD value. This unladen mass MVD may be locked once the engines have been started, and can then no longer be modified.

Similarly, the method may comprise setting STPMPIL the mass MPIL of a crew before the engines 10 are started. A crew operates the human-machine crew mass interface 54, that transmits a crew mass signal to the control unit 60. The control unit 60 decodes the crew mass signal, then deduces therefrom and stores a crew mass MPIL value. This crew mass MPIL may be locked once the engines 10 have been started, and can then no longer be modified.

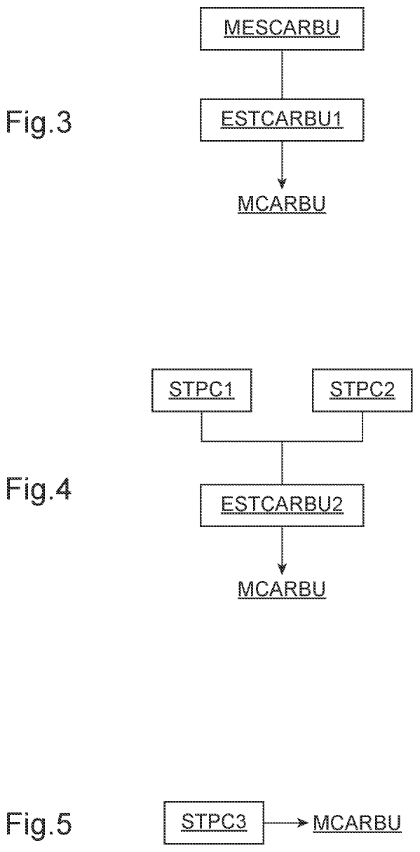

Furthermore, the controller 30 determines the mass of fuel MCARBU. FIGS. 3 to 5 show three possible alternatives for determining the mass of fuel MCARBU.

According to the first alternative of FIG. 3, the training mode comprises measuring MESCARBU a quantity, and possibly a volume, of fuel in the rotorcraft 1, with the gauge 35. The gauge 53 transmits a signal referred to for convenience as the “fuel signal” to the control unit 60, indicating the volume or mass of fuel contained in the tank or tanks 20. The control unit 60 decodes the fuel signal and deduces therefrom the mass of fuel MCARBU during a step of estimating ESTCARBU1 the mass of fuel. For example, the mass of fuel MCARBU is then equal to the product of the volume of fuel measured by the gauge and its density. The density may be stored or indeed set using a human-machine density interface 54.

According to the second alternative of FIG. 4, the training mode comprises setting STPC1 the pre-flight mass or volume of fuel, referred to as the “pre-flight quantity”, with the human-machine interface 51 for setting fuel parameters. This setting STPC1 may be made before the engines 10 are started, the pre-flight mass or the pre-flight volume being locked after said start-up.

This human-machine interface 51 for setting fuel parameters transmits a signal to the control unit 60. The control unit 60 decodes it and stores the pre-flight mass or the pre-flight volume.

The training mode also comprises estimating STPC2 the volume of fuel consumed prior to initialization, with the flowmeter 50 or the gauge 35, for example. The control unit 60 receives a signal from the flowmeter 50 or the gauge 35, and can deduce therefore, at each instant, the volume of fuel consumed since the engines 10 were started.

The controller 30 or the control unit 60 then estimates ESTCARBU2 the mass of fuel as a function of the pre-flight mass or volume of fuel and the consumed volume of fuel, or the density of the fuel. For example, the control unit 60 calculates the arithmetic difference between the pre-flight volume of fuel and the consumed volume of fuel and multiplies this difference by the density of the fuel.

According to the third alternative of FIG. 5, the mass of fuel is set during a setting step STPC3 with the human-machine interface 51 for setting fuel parameters. This human-machine interface 51 for setting fuel parameters transmits a signal to the control unit directly indicating the mass of fuel MCARBU. This setting STPC3 is possibly made before the engines 10 are started, the mass of fuel being locked after said start-up. Alternatively, this setting STPC3 is made during flight, upon initialization of the training mode.

Irrespective of the alternative, the control unit 60 determines the initial mass MINIT during the initialization phase, using the unladen mass MVD, the mass MPIL of a crew present in the rotorcraft 1, and the mass of fuel MCARBU. The control unit 60 can calculate the initial mass MINIT as a function of these inputs, this initial mass MINIT representing the estimated current mass of the rotorcraft 1. The initial mass MINIT may be equal to the sum of the unladen mass MVD, the mass MPIL of a crew present in the rotorcraft 1 and the mass of fuel MCARBU.

Irrespective of how the initial mass MINIT is determined, the training mode comprises determining STPMAX, during flight, the maximum mass, as a function of external conditions and indeed the type of training.

Therefore, initialization of the training mode may involve estimating STPEXT the external pressure PO and the external temperature TO. The external pressure sensor 41 transmits a pressure signal to the control unit 60, the control unit 60 decoding the pressure signal and storing the external pressure PO. Similarly, the external sensor temperature 42 transmits a temperature signal to the control unit 60, the control unit 60 decoding the temperature signal and storing the external temperature TO.

The method possibly comprises selecting SELECTTYP the type of training with the human-machine selection interface 52 at any time before the maximum mass is calculated. A crew operates the human-machine selection interface 52, that transmits a training type signal to the control unit 60. The control unit 60 decodes the training type signal and stores the type of training.

The controller 30, or the control unit 60, then applies a mathematical model providing the maximum mass MMAX as a function of the external conditions or indeed the type of training. Such a model may comprise one or more mathematical laws, an artificial intelligence or the like. The model may be established by tests and/or simulations, for example.

Irrespective of how the maximum mass MMAX and the initial mass MINIT are determined, the training mode comprises comparing STPCOMP the initial mass MINIT with the maximum mass MMAX, using the controller 30, for example using the control unit 60. This comparison STPCOMP may comprise establishing STPR a proportional ratio RAP between the initial mass MINIT and the maximum mass MMAX. The proportional ratio RAP may be equal to the initial mass MINIT divided by the maximum mass MMAX.

Therefore, the training mode comprises determining STPAJUST each control restriction value OEITRAIN with the controller 30, as a function of this comparison and, if applicable, the proportional ratio RAP. This step may be carried out with the control unit 60 and/or with each engine computer 80.

According to the first variant shown in solid lines, the controller 30, or indeed the control unit 60 or the engine computers 80, are configured to estimate STPA1 a calculation control value WLIM as a function of said proportional ratio RAP and the limit control value VLIM. The calculation control value WLIM may be equal to the product of the proportional ratio RAP and the limit control value VLIM. The controller 30 is configured to determine STPA2 each control restriction value OEITRAIN as a function of the associated calculation control value WLIM and a distribution coefficient COEF specific to each control restriction value OEITRAIN. This distribution coefficient may be stored. The sum of the distribution coefficients is equal to one.

According to one quantified example applied to a twin-engine rotorcraft, the proportional ratio is 0.8, the initial mass being equal to 80 percent of the maximum mass. According to this example, the limit control value to which an engine is restricted during the applied emergency rating is 600 newton-meters. Moreover, the overall power during the training mode is distributed equally, resulting in a distribution coefficient equal to 0.5 when two engines 10 are present. The control unit 60 or the engine computers 80 then deduce therefrom that the calculation control value WLIM is equal to 0.8 times 600, i.e., 480 newton-meters, each engine 10 finally being restricted to an engine torque of 480 times 0.5, i.e., 240 newton-meters.

According to the second variant, that is shown in dotted lines, the controller 30, or indeed the control unit 60 or the engine computers 80, are configured to estimate STPA3, for each control restriction value OEITRAIN, an intermediate value VINT as a function of a distribution coefficient COEF specific to each control restriction value OEITRAIN and the limit control value of these engines. The controller 30 is configured to determine STPA4 each control restriction value as a function of said intermediate value VINT and said proportional ratio RAP.

According to one quantified example applied to a twin-engine rotorcraft, the proportional ratio is 0.8, the initial mass being equal to 80 percent of the maximum mass. According to this example, the limit control value to which an engine is restricted during the applied emergency rating g is 600 newton-meters. Moreover, the overall power during the training mode is distributed equally, resulting in a distribution coefficient equal to 0.5 when two engines are present. The engine computers, for example, then deduce therefrom that the intermediate value VINT is equal to 0.5 times 600, i.e., 300 newton-meters, each engine 10 finally being restricted to an engine torque of 300 times 0.8, i.e., 240 newton-meters.

Irrespective of the variant, the training mode then comprises controlling STPREG each engine 10 in a conventional manner, with the controller 30, the control parameter of each engine 10 being controlled in order not to exceed the respective control restriction value OEITRAIN.

The training mode may possibly comprise measuring STPNR a speed of rotation NR of the rotary wing 6 with the rotation speed sensor 66. The control unit 60 receives the rotation speed signal emitted by the sensor 60, decodes it and deduces the current speed of rotation NR of the rotary wing 6 therefrom.

If the speed of rotation NR is greater than a stored threshold NRS, the training mode continues. The training mode may possibly be deactivated by the crew, for example by means of the human-machine interface 55 for activating the training mode.

However, if the speed of rotation NR drops below the threshold NRS, the controller 30 is configured to automatically disengage STPEXIT the training mode with the controller 30. Moreover, the control unit 60 transmits an alert signal to the alerter 65, the alerter 65 being configured to generate STPWARN an alert indicating the disengagement.

Naturally, the present disclosure is subject to numerous variations as regards its implementation. Although several embodiments are described above, it should readily be understood that it is not conceivable to identify exhaustively all the possible embodiments. It is naturally possible to replace any of the means described with equivalent means, the ambit of the present disclosure and the claims being defined by the claims.

What is claimed is:

1. A method for simulating an engine failure on a rotorcraft, the rotorcraft comprising a power plant provided with several engines that together produce an overall power for setting a rotary wing in motion, at least one engine functioning by burning fuel, each engine having a control parameter capped by a controller at a limit control value during at least one emergency rating applicable in the event of failure of another engine, the method comprising a training mode that comprises controlling each engine with the controller in order to simulate an engine failure, the controlling of each engine with the controller comprising capping the control parameter of each engine at a respective control restriction value,
wherein the training mode comprises the following steps:
determining, with the controller, an initial mass of the rotorcraft, at least as a function of an unladen mass of the rotorcraft, a set mass of a crew present in the rotorcraft, and a mass of fuel on-board and estimated;
determining, during flight, with the controller, a maximum mass of the rotorcraft established at least as a function of external conditions;
comparing, during flight, with the controller, the initial mass with the maximum mass; and
determining, with the controller, each control restriction value as a function of comparing the initial mass with the maximum mass and of the limit control value.

2. The method according to claim 1,
wherein the external conditions comprise an external pressure and an external temperature of the air present around the rotorcraft, the training mode comprising estimating the external pressure with an external pressure sensor of the controller and the external temperature with an external temperature sensor of the controller.

3. The method according to claim 1,
wherein the training mode comprises measuring a current quantity of fuel in the rotorcraft with a gauge of the controller, and estimating the mass of fuel as a function of the current quantity of fuel upon initialization of the training mode, the current quantity being a current mass or a current volume.

4. The method according to claim 1,
wherein the training mode comprises setting a pre-flight quantity of fuel with a human-machine interface for setting fuel parameters of the controller, the training mode comprising: i) estimating a quantity of fuel consumed prior to initialization of the training mode; and ii) estimating the mass of fuel as a function of the pre-flight quantity of fuel and the consumed quantity of fuel.

5. The method according to claim 4,
wherein the method comprises setting the pre-flight quantity before the engines are started, using a human-machine interface for setting fuel parameters of the controller, the pre-flight quantity being locked after the start-up.

6. The method according to claim 1,
wherein the mass of fuel is set with a human-machine interface for setting fuel parameters of the controller.

7. The method according to claim 6,
wherein the method comprises setting the mass of fuel before the engines are started, the mass of fuel being locked after the start-up.

8. The method according to claim 1,
wherein the method comprises selecting a type of training with a human-machine selection interface of the controller, determining, during flight, with the controller, the maximum mass, depending on the type of training selected with the human-machine selection interface.

9. The method according to claim 8,
wherein the type of training is chosen from a list comprising: category A training requiring the possibility of continuing the flight after engine failure and category B training requiring the possibility of landing safely after engine failure.

10. The method according to claim 1,
wherein the control parameter is an engine torque or a power.

11. The method according to claim 1,
wherein comparing, with the controller, of the initial mass with the maximum mass comprises establishing a proportional ratio between the initial mass and the maximum mass.

12. The method according to claim 11,
wherein determining, with the controller, of each control restriction value as a function of the comparison, comprises, for each engine: i) estimating a calculation control value as a function of the proportional ratio and the limit control value; then ii) determining the control restriction value as a function of the calculation control value and a distribution coefficient specific to each control restriction value.

13. The method according to claim 11,
wherein determining, with the controller, of each control restriction value as a function of the comparison, comprises, for each engine: i) estimating an intermediate value as a function of a distribution coefficient specific to each control restriction value and the limit control value; then ii) determining each control restriction value as a function of the intermediate value and the proportional ratio.

14. The method according to claim 1,
wherein the method comprises setting the unladen mass before the engines are started, with a human-machine unladen mass interface of the controller, and setting the mass of a crew present in the rotorcraft, before the engines are started, with a human-machine crew mass interface of the controller, the unladen mass and the mass of a crew present in the rotorcraft being locked after the start-up.

15. The method according to claim 1,
wherein the method comprises measuring a speed of rotation of the rotary wing with a rotation speed sensor of the controller, automatically disengaging the training mode with the controller as soon as the speed of rotation is less than a stored threshold, and generating an alert indicating the disengagement.

16. A rotorcraft comprising a power plant provided with several engines that together produce an overall power for setting a rotary wing in motion, each engine producing a power capped by a controller at a limit power value when at least one emergency rating is applied in the event of failure of at least one other engine,
wherein the controller is configured to apply the method according to claim 1.
